(19) United States
(12) Patent Application Publication
(10) Pub. No.: US 2019/0007044 A1
(43) Pub. Date: Jan. 3, 2019

(54) METHOD FOR MANAGING A CAPACITIVE KEYBOARD FITTED TO A MOTOR VEHICLE

(71) Applicant: DURA AUTOMOTIVE SYSTEMS SAS, Bievres (FR)

(72) Inventor: Eric DURAND, Louveciennes (FR)

(73) Assignee: Dura Automotive Systems SAS, Bievres (FR)

(21) Appl. No.: 16/064,489

(22) PCT Filed: Dec. 13, 2016
(86) PCT No.: PCT/FR2016/053347

§ 371 Date: Jun. 21, 2018

(30) Foreign Application Priority Data
Dec. 22, 2015 (FR) 1563150

(51) Int. Cl. H03K 17/96; G06F 3/02; G06F 3/01; B60R 25/23

(52) U.S. Cl. CPC H03K 17/9622; G06F 3/0219; H03K 2217/960705; B60R 25/23; H03K 2217/96062; G06F 3/016

(57) ABSTRACT

A method for managing a capacitive keyboard fitted to a motor vehicle, the capacitive keyboard comprising a plurality of keys connected to an electronic control unit and having a tactile function, the method including the steps of: performing a measurement of capacitance for each of the keys; and temporarily deactivating the tactile function of the keyboard if, for at least one of the keys, the capacitance is greater than or equal to a predetermined threshold value. The disclosure also relates to a motor vehicle comprising a capacitive keyboard and an electronic control unit configured for implementing such a method.

### TECHNICAL FIELD

The present disclosure relates to a method for managing a capacitive keyboard fitted to a motor vehicle. The disclosure also relates to a motor vehicle comprising a capacitive keyboard and an electronic control unit configured for implementing such a method.

The disclosure relates to the field of capacitive keyboards fitted to motor vehicles, in particular for unlocking or locking doors.

### BACKGROUND

As for example mentioned in document US2010315267A1, it is known to unlock the doors of a vehicle by pressing a series of keys according to a predetermined sequence, and to lock them by pressing two keys simultaneously for a predetermined duration. This document also mentions the use of an algorithm for suppressing a touch-sensitive zone, seeking to avoid the accidental activation of a key. This algorithm accounts for the existence of multifunctional keys, which makes it relatively complex.

US2015360646A1 describes another example of a system for locking and unlocking doors of a vehicle. The system comprises two user interfaces, grouped together on a single capacitive keyboard or distributed over two separate capacitive keyboards.

### SUMMARY

The aim of at least some implementations of the present invention is to propose an improved method for managing a capacitive keyboard, in particular in case of rain shower.

To that end, the disclosure relates to a method for managing a capacitive keyboard fitted to a motor vehicle, the capacitive keyboard comprising a plurality of keys connected to an electronic control unit and having a tactile function, this method being characterized in that it comprises the steps consisting of: performing a measurement of capacitance for each of the keys; and temporarily deactivating the tactile function of the keyboard if, for at least one of the keys, the capacitance is greater than or equal to a predetermined threshold value.

Thus, the disclosure makes it possible to improve the operation of the capacitive keyboard in case of rain shower.

Unlike the pressing of a finger, which decreases the capacitance, the presence of water droplets on the keys increases the capacitance. Conversely, the presence of a large drop of water on one of the keys may decrease the capacitance and be detected as “false pressure” on this key.

Owing to the disclosure, the tactile function of the capacitive keyboard is deactivated at the beginning of the rain shower, which makes it possible to avoid false detections due to the striking or formation of large drops of water on the keys.

In other words, an anti-touch function of the keyboard is activated in case of rain shower.

According to other advantageous features of at least certain implementations of the invention, considered alone or in combination:
The method also comprises a step consisting of reactivating the tactile function of the keyboard if, for each of the keys, the capacitance is below the predetermined threshold value for a predetermined duration.
The predetermined duration is 300 milliseconds.
The predetermined threshold value is defined as 5% greater than a reference value of the capacitance, corresponding to the keys when idle.
The measurement of capacitance is done via electrodes positioned below the keys and connected to the electronic control unit.
The measurement of capacitance is done continuously.
The measurement of capacitance is done at regular intervals.
The disclosure also relates to a motor vehicle comprising a capacitive keyboard and an electronic control unit configured for implementing the method defined above.

### BRIEF DESCRIPTION OF THE DRAWINGS

Certain embodiments of the invention will be better understood upon reading the following description, given solely as a non-limiting example, and made with reference to the accompanying figures in which:

FIG. 1 is a front view of a motor vehicle door capping, comprising a capacitive keyboard connected to an electronic control unit;

FIG. 2 is a larger-scale view of the capacitive keyboard of FIG. 1; and

FIGS. 3 to 6 show graphs illustrating different signals sent to the electronic control unit, based on outside stresses exerted on the surface of a key of the keyboard.

### DETAILED DESCRIPTION OF SOME EMBODIMENTS

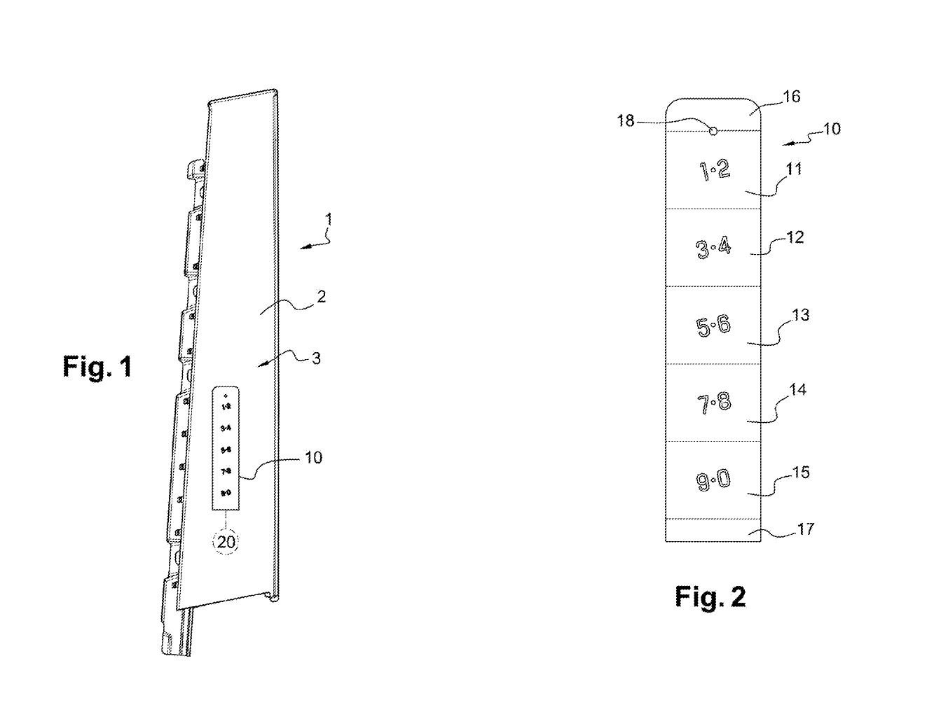

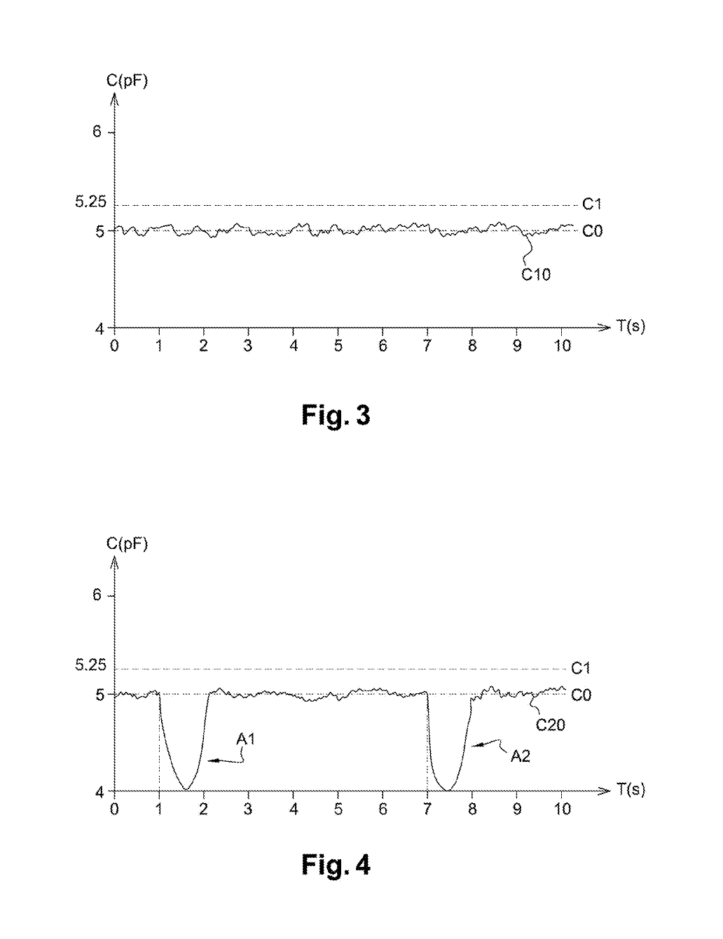

FIGS. 1 and 2 show a capacitive keyboard 10, equipping a door capping 2 of a motor vehicle 1.

The keyboard 10 comprises five keys 11, 12, 13, 14 and 15 connected to an electronic control unit 20 also equipping the capping 2. The unit 20 is in turn connected to the on-board computer of the vehicle 1. In practice, the unit 20 is located as close as possible to the keyboard 10 in order to be able to detect, under good conditions, a capacitance variation of the electrodes, as explained below. Alternatively, the unit 20 can be integrated directly into the on-board computer of the vehicle 1.

The keyboard 10 has a tactile function, known in itself. The keys 11-15 are accessible on the outer surface 3 of the capping 2. Thus, a user can generate signals intended for the electronic control unit 20 by pressing on the surface of the keys 11-15.

These signals are in particular intended to control the opening or closing of the doors of the vehicle 1, by typing a code corresponding to a predetermined pressing sequence on the keys 11-15.

The tactile function of the keyboard 10 is activated by default, but can be deactivated under certain conditions, as outlined below.

The keyboard 10 is a capacitive system, known in itself. The keyboard 10 includes a capacitive layer, designed to accumulate electric charges. When the user touches the surface of the keyboard 10 with his finger, some of these charges are transferred to him. The charges leaving the capacitive layer create a quantifiable deficit, thus making it possible to detect pressing on a given key 11-15. For example, the variations in charges can be measured owing to electrodes positioned below the keyboard 10 and connected to the unit 20. The capacitance C associated with each key 11-15 can be measured and transmitted to the unit 20, either continuously or at regular intervals.

The keys 11-15 each have two figures, namely the figures “1” and “2” for the key 11, the figures “3” and “4” for the key 12, the figures “5” and “6” for the key 13, the figures “7” and “8” for the key 14, and the figures “9” and “0” for the key 15. This makes it possible to make the keyboard 10 more compact, compared with a keyboard having ten keys.

A pressing sequence on the keys 11-15 thus makes it possible to send a numerical code to the unit 20, which then controls the opening or closing of the doors when the code is correct.

In practice, pressing on the key 11 sends the unit 20 a signal indifferently corresponding to the two figures “1” and “2”, and so forth for the keys 12 to 15. This makes it possible to define a numerical code based on ten digits, without needing to press twice to type the even numbers.

The keyboard 10 also has non-capacitive spaces 16 and 17, respectively located above the key 11 and below the key 15. Alternatively, the spaces 16 and 17 can be capacitive and constitute keys corresponding to other functionalities of the keyboard 10, which will not be outlined, since they are not part of the subject matter of the present disclosure.

The keyboard 18 also includes a light-emitting diode 18 located between the key 11 and the space 16, for example making it possible to indicate to the user that the pressing he has exerted on a key 11 to 15 has indeed been detected by the unit 20.

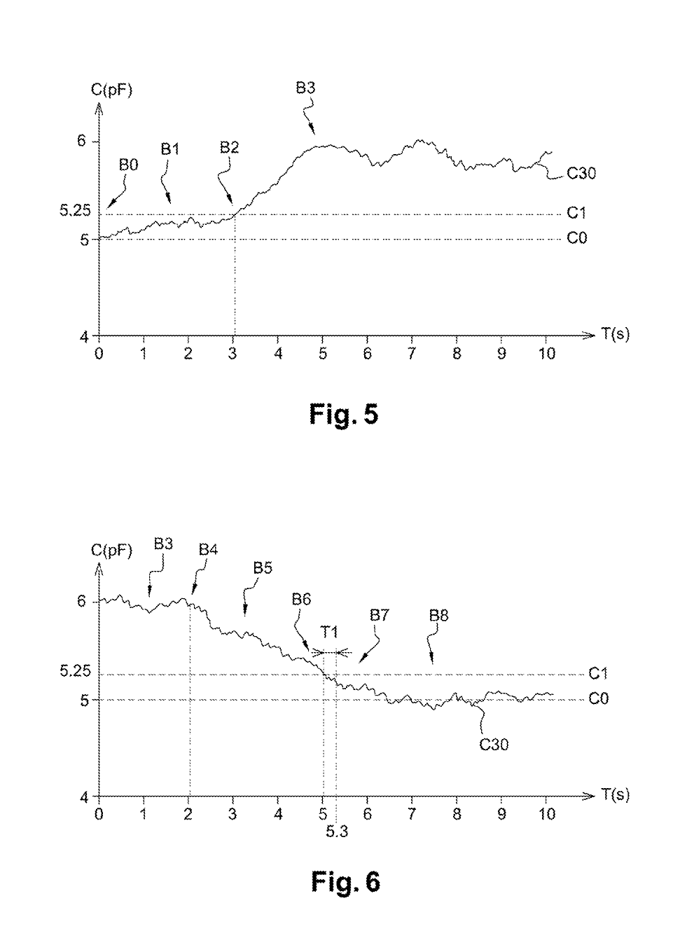

FIGS. 3 to 6 show graphs illustrating different signals sent to the electronic control unit 20 from a given key 11-15, based on stresses exerted or not exerted on the surface of this key.

On these graphs, the x-axis corresponds to a time T in seconds (s), while the y-axis corresponds to a capacitance C in picofarads (pF).

A reference value C0 and a threshold value C1 are shown in dotted lines. The reference value C0 in particular depends on the construction of the keyboard 10, the arrangement of the measuring electrodes, and the configuration of the control unit 20. In the example of the figures, this reference value C0 is equal to 5 pF. The threshold value C1 is predetermined during the configuration of the control unit 20, based on the desired sensitivity to activate the anti-tactile function of the keyboard 10. In the example of the figures, this threshold value C1 is defined to be 5% greater than the reference value C0, i.e., equal to 5.25 pF.

FIG. 3 shows a signal C10 corresponding to a key 11-15 when idle, sent to the unit 20 when this key does not receive any outside stress. The capacitance C of the signal C10 varies slightly around the reference value C0. Indeed, the reference value C0 is the theoretical value of the capacitance C when idle, while the signal C10 is generated from actual measurements of the capacitance C when idle.

FIG. 4 shows a signal C20 corresponding to two successive presses A1 and A2 on a given key 11-15. While the user presses on this key, the capacitance C decreases by about 20%, temporarily going from 5 to 4 pF. The unit 20 is configured to interpret each capacitance C variation and thus to detect the presses A1 and A2.

FIGS. 5 and 6 illustrate a signal C30 recorded during a rain shower, for a given key 11-15. These graphs include different distinct phases B0, B1, B2, B3, B4, B5, B6, B7 and B8. For simplification reasons, the time measurement starts at 0 in the graph of FIG. 6, with the understanding that phase B3 extends over both of the graphs of FIGS. 5 and 6.

Phase B0 represents the very beginning of the rain shower, while phase B1 represents the first seconds of the rain shower. Drops of rain fall on the keyboard 10, or stream on the surface 3 of the capping 2 up to the keyboard 10.

Unlike the pressing of a finger, which decreases the capacitance C, the presence of droplets of water on the keys 11-15 increases the capacitance C. Conversely, the presence of a large drop of water on one of the keys 11-15 may decrease the capacitance C and be detected as a “false press” on this key. The invention therefore aims to temporarily deactivate the tactile function of the keyboard 10 during a rain shower to avoid these false detections.

Phase B2 represents the moment where the capacitance C of the signal C30 reaches the predetermined threshold value C1. At this moment, the unit 20 temporarily deactivates the tactile function of the keyboard 10. In other words, the unit 20 temporarily activates the anti-tactile function of the keyboard 10. The unit 20 is configured to temporarily deactivate the tactile function if the capacitance C is greater than or equal to the threshold value C1 for at least one of the keys 11-15. Thus, even if large drops of rain strike the keys 11-15 of the keyboard 10 or form on one of the keys 11-15, false detections are avoided.

Phase B3 represents the continuation of the rain shower, while more and more droplets of water stream over the keyboard 10. For each key 11-15, the capacitance C of the signal C30 increases or decreases based on the presence of droplets on that key.

Phase B4 represents the moment where the rain shower loses intensity, while phase B5 represents the gradual stopping of the rain shower. The droplets of water still stream over the keyboard 10, but no longer accumulate on the keys 11-15.

Phase B6 represents the moment where the capacitance C of the signal C30 again reaches the threshold value C1 and passes back below it. The unit 20 is configured to reactivate the tactile function of the keyboard 10 if, for all of the keys 11-15, the capacitance C is less than the threshold value C1 for a predetermined duration T1. According to at least one embodiment, the duration T1 may be set at 300 milliseconds.

Phase B7 represents the moment where the duration T1 has elapsed from phase B6, for the key 11-15 corresponding to the signal C30. If the capacitance C is still greater than or equal to the threshold value C1 for other keys, then the unit 20 maintains the deactivation of the tactile function of the keyboard 10. If the capacitance C is once again below the threshold value C1 for a duration T1 for each of the keys 11-15, then the unit 20 reactivates the tactile function of the keyboard 10.

Lastly, phase B8 represents the gradual return to the idle state of the key 11-15 corresponding to the signal C30.

Furthermore, the keyboard 10 can be configured differently from FIGS. 1 and 2, while the method for managing the keyboard 10 can be implemented differently from FIGS. 3 to 6, without going beyond the scope of the invention.

Furthermore, the technical characteristics of the various embodiments and variants mentioned above can be, in whole or for some of them, combined with each other. Thus, the management method and the keyboard 10 can be adapted in terms of functionalities, performance and implementation cost.

1. A method for managing a capacitive keyboard fitted to a motor vehicle, the capacitive keyboard comprising several keys connected to an electronic control unit and having a tactile function, wherein the method comprises the steps consisting of:
performing a measurement of capacitance for each of the keys; and
temporarily deactivating the tactile function of the keyboard if, for at least one of the keys, the capacitance is greater than or equal to a predetermined threshold value.

2. The method according to claim 1, wherein the method also comprises a step consisting of reactivating the tactile function of the keyboard if, for each of the keys, the capacitance is below the predetermined threshold value for a predetermined duration.

3. The method according to claim 2, wherein the predetermined duration is 300 milliseconds.

4. The method according to claim 1, wherein the predetermined threshold value is defined as 5% greater than a reference value of the capacitance, corresponding to the keys when idle.

5. The method according to claim 1, wherein the measurement of capacitance is done via electrodes positioned below the keys and connected to the electronic control unit.

6. The method according to claim 1, wherein the measurement of capacitance is done continuously.

7. The method according to claim 1, wherein the measurement of capacitance is done at regular intervals.

8. A motor vehicle, comprising a capacitive keyboard and an electronic control unit configured to implement the method according to claim 1.
